(19) United States
(12) Patent Application Publication
(10) Pub. No.: US 2011/0263077 A1
(43) Pub. Date: Oct. 27, 2011

(54) METHOD OF ASSEMBLING SEMICONDUCTOR DEVICES INCLUDING SAW SINGULATION

(75) Inventors: Zhigang BAI, Tianjin (CN); Zhijie Wang, Tianjin (CN); Jinzhong Yao, Tianjin (CN)

(73) Assignee: FREESCALE SEMICONDUCTOR, INC, Austin, TX (US)

(21) Appl. No.: 13/025,143

(22) Filed: Feb. 10, 2011

(30) Foreign Application Priority Data
Apr. 23, 2010 (CN) 201010166155.4

(51) Int. Cl. H01L 21/50

(52) U.S. Cl. 438/112; 257/E21.499

(57) ABSTRACT

A method of assembling semiconductor devices for surface mounting includes forming an array of lead frames in which supporting frame structures of adjacent lead frames include an intermediate common bar connecting on both its sides with sets of leads of the respective adjacent lead frames. The semiconductor devices are singulated by sawing through the leads on each side of the common bars without sawing the common bars longitudinally. The material sawn off from the common bars in a first direction is removed by washing it away before sawing off the intermediate common bars that run in an orthogonal direction. The supporting frame structures include bars surrounding the array and singulation includes sawing beside the surrounding bars to saw them off before sawing off the intermediate common bars.

### BACKGROUND OF THE INVENTION

The present invention relates to a method of assembling semiconductor devices including saw singulation and to semiconductor devices assembled using such a method.

Semiconductor devices, such as integrated circuits, include a semiconductor die (or chip) in a package with leads presenting exposed electrical contact surfaces. The devices may be mounted on a support with electrical connections, such as a printed circuit board (‘PCB’), for example. Using surface mount technology the electrical contact surfaces of the leads can be soldered directly to corresponding pads on the support, providing mechanical attachment as well as electrical connection.

A surface mount device typically includes an electrically insulating molding material that encapsulates the semiconductor die so that the device has a top face and a bottom, active face, which are generally rectangular or square, and transversely extending edges. The molding compound may encapsulate the semiconductor device completely or define an air cavity that is then sealed with a ceramic or plastic lid. Typically, the package has a pair of sets of leads on opposite sides of the package (‘dual in-line’) or two orthogonal pairs of sets of leads on respective sides of the package (‘quad’). Each set of leads is formed of discrete elements arranged side by side at intervals along the corresponding side of the active face of the package, the electrical contact surfaces extending perpendicularly to the side of the active face for soldering to the electrical connections of the support. In a kind of package referred to as ‘no-lead’ or ‘leadless’, the ends of the leads terminate at and are flush with the side edges of the packages. Such a no-lead device may have a smaller size than a device with leads projecting beyond the sides of the encapsulation or molding material. The solder process during mounting the no-lead device on the support may form a fillet of solder rising up the ends of the leads, facilitating a visual check of the quality of the solder joint between the contact surfaces at the active face of the device and the electrical connections of the support.

When assembling the device, the semiconductor die may be mounted on a pad or flag formed from the same material as the leads, which is usually a metal, such as copper, which may be plated. The die pad may be exposed at the bottom face of the package to assist cooling the die. Alternatively, the die may be mounted on the discrete leads, the die and the leads being supported mechanically by the encapsulation material. The leads may be connected electrically to bond pads on the die with bond wires, of gold, copper or aluminum for example, accommodating differential thermal expansion of the die and the package materials.

A prevalent technique used in manufacturing such a surface mount device includes forming an array of lead frames in a strip or sheet of electrically conductive material, usually metal, by etching and/or stamping for example. Each lead frame in the array includes the sets of leads, respective supporting frame structures, and any die pad for supporting the die. The discrete elements of each set, which will form the leads of the device after singulation, are disposed side by side at intervals and include respective contact portions presenting respective electrical contact surfaces. The array of lead frames may be a single strip but typically is a two-dimensional array, with the supporting frame structure of the array comprising surrounding bars on the outer edges of the array and intersecting intermediate bars common to adjacent lead frames.

In a typical surface mount semiconductor device assembly or packaging process using lead frames, the semiconductor dies are mounted on and connected electrically to respective ones of the lead frames, with the encapsulation material then being molded over and around the lead frame strip or sheet so as to encapsulate the integrated circuit dies, the leads of each of the lead frames, and the bond wires. The individual devices are then separated by a singulation process, in which the lead frame strip or sheet is cut apart. The singulation may be a punch operation. However, punch singulation normally requires the lead frames to be individually molded, leaving a gap in the encapsulation material between adjacent devices for the passage of the punch tool. Saw singulation enables a smaller distance between each individual package and therefore improves lead frame utilization. Saw singulation also enables the molding compound to be applied over the entire array, being cut subsequently during the singulation process. During saw singulation, a saw blade is advanced along ‘saw streets’ that extend between the discrete electrical contact elements of adjacent lead frames, so as to cut off the supporting frame structures of the lead frames and separate the individual devices from each other.

Application Note 1902 Rev. 4.0, 9/2008,“Quad Flat Pack No-Lead (QFN), Micro Dual Flat Pack No-Lead (uDFN)”, published by Freescale Semiconductor, Inc. at http://www.freescale.com/files/analog/doc/app note/AN1902.p df, U.S. Pat. No. 7,183,630 and the Article “Saw Singulation Characterization on High Profile Multi Chip Module Packages with Thick Leadframe” by Nazrul Anuar and Amalina Taib in the Proceedings of the IEEE 2004 Electronics Packaging Technology Conference reference 0-7803-8821-6/04 describe surface mount semiconductor device lead frame saw singulation processes.

Saw singulation can give rise to defects at the sawn edge of the semiconductor devices. Defects noted in the above cited IEEE article include chipping of the molding compound, smearing of the contact material laterally over the sawn surface of the molding compound with consequent risk of short-circuit between adjacent leads, and formation of burrs of the contact material below the sawn ends of the leads, which can degenerate solder joint reliability and surface mounting quality.

U.S. Pat. No. 6,544,817 discloses a singulation method in which the saw streets are positioned at the electrical lead elements instead of along the common bars of the frame structure between adjacent lead frames. However, saw blade life is still a preoccupation and there remains a risk of damage to the saw blade during singulation.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1 is a bottom plan view of a conventional packaged quad lead semiconductor device after singulation;

FIG. 2 is a partial perspective view of the bottom and two sides of the encircled region A of the packaged device of FIG. 1;

FIG. 3 is a cross-sectional view illustrating part of a lead frame array of a dual lead packaged device during assembly;

FIG. 4 is a diagrammatic sectional view of the packaged of FIG. 1;

FIG. 5 is an enlarged view of part of the lead frame array shown in FIG. 3;

FIG. 6 is a plan view of part of a lead frame array used in a method of assembling semiconductor devices in accordance with one embodiment of the present invention, given by way of example;

FIG. 7 is an enlarged view of part of the lead frame array of FIG. 6 after encapsulation and during singulation during a method of assembling semiconductor devices in accordance with one embodiment of the present invention, given by way of example; and

FIG. 8 is a flow chart of a method of assembling semiconductor devices in accordance with one embodiment of the present invention, given by way of example.

### DETAILED DESCRIPTION OF PREFERRED EMBODIMENTS

The present invention provides a method of assembling a semiconductor device. The device is assembled by putting together a semiconductor die and a lead frame and encapsulating the die and lead frame to form a packaged device. The lead frames are provided in arrays, with adjacent lead frames being separated from each other with common connection bars. After encapsulating the die, lead frame and any wires electrically connecting the two together, adjacent devices are separated from each other with a singulation process. In one embodiment of the present invention, a saw singulation operation is performed in which a saw cuts along each side of the common connection bars, but does not cut the bar itself, as is done in the prior art. In another embodiment of the present invention, the leads of each lead frame that are connected and orthogonal to the common bars include recesses or cavities. The saw blade cuts the leads at the cavities, which means the saw blades cut even less metal because the leads are thinner at the cavities. Also according to the present invention, the cavities do not extend across the common bars and into a lead of another lead frame. Rather the common bar is not thinned, and thus the common bars provide good support to the lead frames.

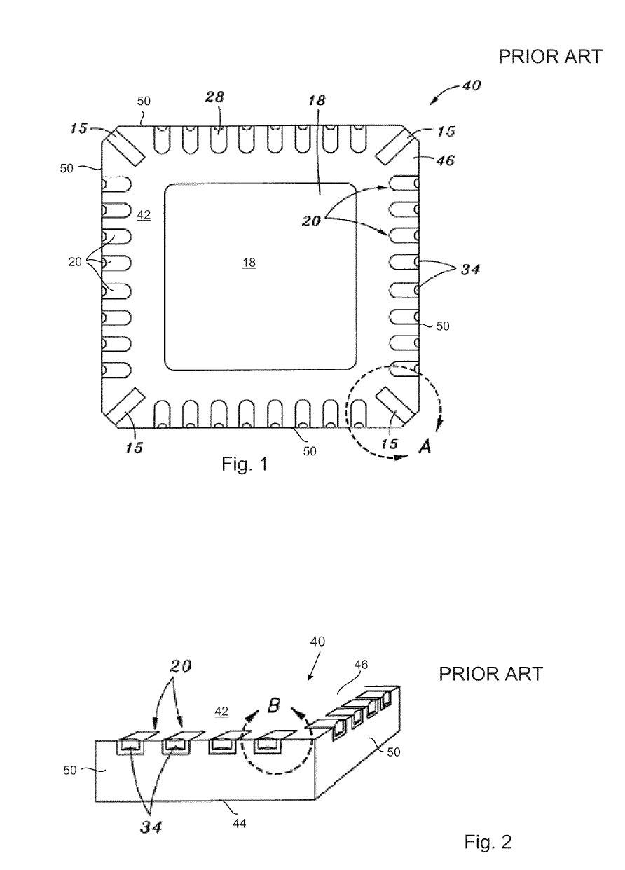

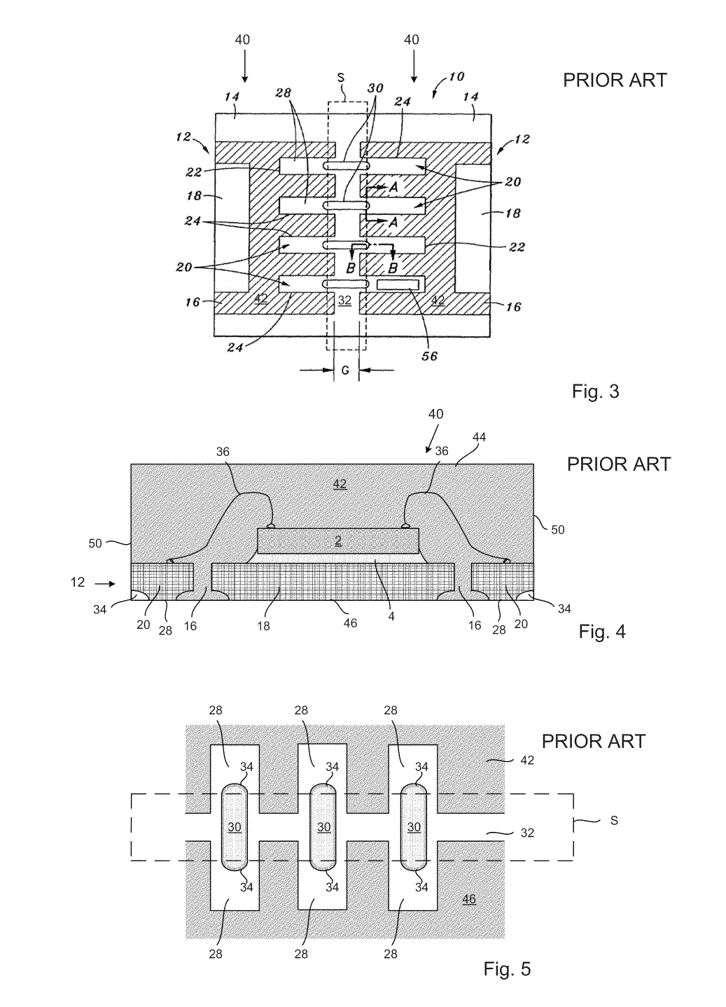

FIGS. 1 to 3 and 5 show a conventional packaged semiconductor device 40 at various stages of manufacture such as that disclosed in U.S. Pat. No. 7,183,630. Although a person of skill in the art will note that FIGS. 1-2 illustrate a quad lead type device and FIG. 3 illustrates a dual lead type device, for ease of description, these will be treated as showing the same device, i.e., device 40, since the method of the present invention is applicable equally to both quad and dual lead type devices. FIG. 4 shows variations on the device 40 of FIGS. 1 to 3 and 5. The device 40 may be made by a process according to an embodiment of the present invention.

The device 40 shown in FIGS. 1 to 4 includes a package body 42 formed by the hardening of electrically insulating plastic encapsulation material, or molding compound, which is applied to a lead frame array 10 such as that shown in FIG. 3. The successive lead frames 12 of the array 10 may extend in a two dimensional matrix presenting rows and columns of lead frames 12. A saw singulation process separates the devices 40 from each other by cutting and separating both the individual frames 12 of the lead frame array 10 and the plastic encapsulation material in a manner completing the formation of the package body 42 of each device 40. The completely formed package body 42 defines a top face 44 and an opposing bottom, active face 46, which are generally rectangular. A peripheral edge surface 50 extends transversely to the top and bottom faces 44, 46 of the package body 42.

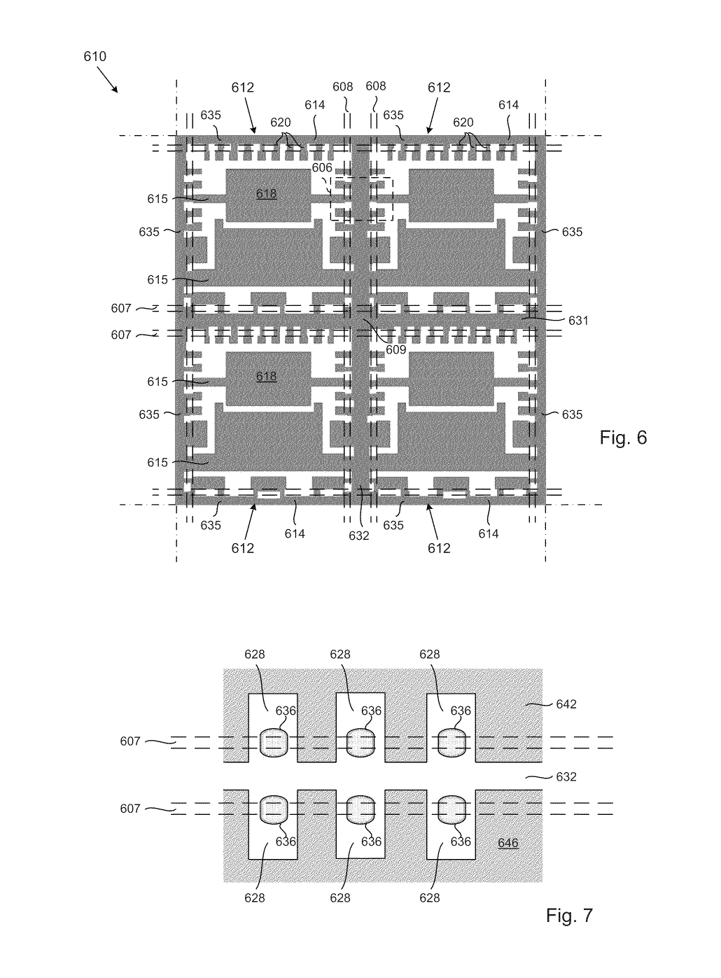

FIG. 3 shows part of a dual in-line type lead frame array 10 as described in U.S. Pat. No. 7,183,630. Each lead frame 12 of the array 10 includes a frame structure 14 that surrounds a centrally positioned opening 16 into which the molding compound, shown diagonally hatched, penetrates during encapsulation. The lead frame 12 may include a die pad 18 disposed within the opening 16. The die pad 18 may be supported by the frame structure 14 before encapsulation and singulation by a plurality of tie bars 15 (FIG. 1) that extend between the frame structure 14 and respective ones of four corner regions defined by the die pad 18 to provide such support. In another configuration, as shown in FIG. 6, the die pad 18 (element 618 in FIG. 6) may be supported by a plurality of tie bars 615 situated at intermediate positions in sides of the frame structure 14 (element 614 in FIG. 6).

Each lead frame 12 further comprises sets of discrete, mostly elongate electrical contact elements or leads 20 disposed side by side at intervals along respective sides of the active face 46 of the device 40 and extending perpendicularly to the side of the corresponding active face. In the completed quad ‘no-lead’ package illustrated in FIGS. 1 and 2, sets of leads 20 are disposed on all four sides of the active face 46 and are exposed at the active face 46 and at the side edges 50 of the package for soldering to the electrical connections of the support. In the completed dual in-line lead frame strip configuration of FIG. 3, sets of leads 20 are disposed on only two opposed sides of the active face 46.

As shown in FIGS. 1, 2 and 4, the ends of the leads 20 of the completed device 40 terminate at least approximately flush with the sides of the singulated, completed packages. Before singulation, as shown in FIG. 3, the leads 20 are integrally connected to and supported by the frame structure 14 and extend inwards into the opening 16 toward the peripheral edge of the die pad 18. In each lead frame array 10, the frame structures 14 include intermediate elongate bars 32, which are common to adjacent lead frames 12. The frame structures 14 are cut away and discarded during singulation.

Before encapsulation, semiconductor dies 2 are mounted on and attached to respective lead frames, either on die pads 18 using tape or thermally conductive adhesive 4, as shown in FIG. 4, or on the leads 20. A single semiconductor die may be mounted on each lead frame 12, or more than one semiconductor die may be mounted on each lead frame 12. Electrical connections may be made, in known manner, for example between bonding pads (not shown) on the die 2 and respective ones of the leads 20 using wires 36, for example of gold. The lead frames 12 are then encapsulated by applying the molding material to the lead frame array 10, either to the entire lead frame array, or to form individual moldings for the individual devices, possibly with the addition of a lid for an air cavity type device. In the case where the dies 2 are mounted on die pads 18, the configuration of the lead frames 12 and the application of the molding material 42 to the lead frames 12 may be such that the die pads 18 (if any) are exposed within the bottom, active faces 46 of the packaged semiconductor devices 40 to provide increased cooling for the die. In another configuration, the bottom surface of the die pad 18 is also encapsulated, only the leads 20 of the lead frames being exposed in the bottom, active faces 46 of the packaged semiconductor devices 40.

In accordance with the present invention, the leads are exposed within the active face 46 of the package body 42. In addition, the outer ends of the leads 20 are exposed within the side edges 50 of the package body 42. As shown, the presently preferred embodiment of the invention has recesses 34 formed in the bottoms of the electrical contact surface portions 28 and the exposed outer ends of the leads 20 of the semi-completed conductor package 40. During solder mounting of the device 40 on its support (e.g., PCB), solder can reflow up into the recesses 34. The electrical contact surface portions 28 and outer end, including the recesses 34, of each lead 20 (which are exposed within the package body 42) may have a plating layer applied to facilitate soldering to the support.

As shown in FIGS. 3 and 5, the recesses 34 of the leads 20 of adjacent lead frames 12 within the same column or row, may be formed by semi-etching, that is to say etching the material of the lead frame array part-way through its thickness. The semi-etching may form elongate cavities 30 extending across the common bars 32 of the outer lead frame structures 14 common to adjacent lead frames, so that the opposite ends of the cavities 30 form the recesses 34 in the ends of the juxtaposed leads 20 of the adjacent lead frames. The saw singulation subsequently cuts away the rest of the cavities 30 with the material of the common bars 32 of the outer frame structures 14.

A saw street S of the lead frame array 10 extends along the common bars 32 common to each pair of adjacent lead frames 12. The passage of a saw blade along each saw street S separates the adjacent lead frames 12 from each other. Orthogonal row and column saw streets S extend within the two-dimensional array 10.

In the manufacturing process disclosed in U.S. Pat. No. 7,183,630, the saw blade is the same width as each of the saw streets S and straddles the intermediate common bar 32 of the outer frame structure 14 while it is sawing. Thus, during the saw singulation process, the saw blade cuts along each saw street S longitudinally, cutting into and along the common bars 32 of each of the outer lead frame structures 14, which reduces all the metal material of the common bars 32 to swarf, which is discarded, and further removes or severs a portion of each of the leads 20 to form their outer ends at the peripheral edge surfaces of the package body 42, in addition to cutting the molding compound 42. Accordingly, as the saw blade cuts along each saw street S, it is always continuously cutting the metal of the common bars 32 longitudinally as well as cutting the metal of the leads 20, even if the amount of metal cut is less when the saw blade passes through the aligned spaces separating the leads 20 from each other and through the cavities 30 (attributable to the reduced thickness of the metal). However, the continuous longitudinal metal cutting of the saw blade prevents the blade from sharpening itself and notably results in excessive smearing and burrs, with attendant risk of the defects leading to short circuits between adjacent leads 20 and insufficient coplanarity of the bottom, active faces 46 the completed devices 40.

FIGS. 6 and 7 show an array 610 of lead frames 612, and a schematic detail of an area 606 (FIG. 6) between two of the lead frames 612 in the array 610 after application of molding compound and during singulation, in an example of a method of assembling semiconductor devices for surface mounting in accordance with an embodiment of the present invention. The method illustrated in FIGS. 6 and 7 is applicable to making a semiconductor device of the kind shown in FIGS. 1, 2 and 4, as well as other semiconductor devices. The method illustrated in FIGS. 6 and 7 comprises either forming an array 610 of lead frames 612 in a sheet of electrically conductive material or using lead frames 612, as described below. Each of the lead frames 612 comprises at least one pair of sets of leads 620 disposed at opposite sides of the corresponding lead frame 612 and respective supporting frame structures 614. The leads 620 present respective electrical contact surface portions 628. The supporting frame structures 614 comprise intersecting orthogonal intermediate common row and column bars 631 and 632 between adjacent ones of the lead frames 712. Sets of the leads 620 of the respective adjacent lead frames 612 connect with and extend transversely to the common bars 631 and 632. A semiconductor die, such as 2, (not shown in FIGS. 6 and 7) is mounted in each of the lead frames 612 and in this embodiment the dies are mounted and attached to flags 718. The dies also are connected electrically with the leads 620 of the corresponding lead frames (for example by wire bonding wires between the leads and die bonding pads). A molding compound is applied to the dies and lead frames and at least partially encapsulates the semiconductor dies, lead frames, and wires connecting the dies and lead frames. Active faces 46 are at least partially exposed and opposite faces 44 (not shown in FIGS. 6 and 7) of the resulting semiconductor devices with the leads 620 exposed at the active faces of the semiconductor devices 40.

With the dies attached and connected to the lead frames 712, the lead frames 612 are then separated from each other with a singulation process. In this embodiment of the invention, singulating includes sawing through the leads 620 on opposing sides of the common bars 631 and 632 without sawing the common bars 631 or 632 longitudinally. As shown in FIGS. 6 and 7, a saw blade passes on each side of the common bar 631 and 632 in a row saw street 607 or a column saw street 708, which is spaced laterally from the common bar 631 or 632. The saw operation may include separate passes of a single saw blade, first on one side of the common bar 631 or 632, then on the other side. However, in another example of an embodiment of the invention, a ‘gang’ saw having a pair of saw blades cuts simultaneously on both sides of the common bar 631 or 632. The common bar 631 or 632 itself is not sawn longitudinally nor reduced entirely to swarf.

Since the saw blades do not cut the elongate common bar 631 or 632 longitudinally, but rather saw beside the common bar 631 or 632, much less metal swarf is produced than as compared with the conventional process that cuts right along the common bars. The process allows the blade diamond grit to preserve its self-sharpening characteristics. Also, the width of each saw blade and of each saw street 607 and 608 can be substantially less than the common bar 631 or 632 and of the saw street S of FIG. 3, again reducing the amount of metal swarf produced. In this way, the risk and size of metal smearing and burrs are reduced significantly and the saw blade wear rate is reduced significantly, which results in better singulation quality and lower manufacturing cost.

U.S. Pat. No. 6,544,817 discloses a singulation method in which the saw streets are positioned at the electrical contact elements instead of along the common bars of the frame structure between adjacent lead frames. However, sawing off the intermediate row and column common bars by sawing in two orthogonal directions can reduce saw blade life, with a remaining risk of damage to the saw blade during singulation.

In one embodiment of the present invention, the saw singulation process includes sawing in a first direction through the leads 620 in saw streets 607 or 608 on each side of each side of each row or column common bar 631 or 632 without sawing the common bar 631 or 632 itself longitudinally so as to saw off material from the corresponding common bars. The saw blades saw transversely through the orthogonal common bars 632 or 631, as well as the leads 720, but it will be appreciated that the amount of swarf generated by sawing transversely through the width of the orthogonal common bars 632 is much less than sawing continuously longitudinally of the common bars 632, as is the case in FIGS. 3 and 5. Since the sets of pairs of saw streets 607 and 608 extend orthogonally, sawing in a first direction 607 or 608 and then in an orthogonal direction 608 or 607 could leave small chips at the intersections 609 of the saw streets, as shown in FIG. 6. Use of a tape saw, in which adhesive tape is used to support the lead frame array 610 during singulation especially causes such chips to come unstuck, since such small chips adhere weakly, and move into the path of the saw blades with the attendant risk of damage to the saw blade.

In one embodiment of the present invention, the material sawn from the intermediate common bars 631 or 632 in the first direction 707 or 708 is removed before sawing off material from the intermediate common bars 632 or 631 in the orthogonal direction 708 or 707.

In one embodiment of the present invention, the lead frame array 610 is singulated with a jig singulation saw, in which the lead frames 612 are individually supported in a jig, by vacuum suction for example. The sawn-off material from each common bar 631 or 632 is washed away as it is sawn off, by a stream of cooling water directed at the contact between the rotating saw blade and the lead frame array 610. Most of the sawn-off material of each common bar 631 or 632 is washed away completely during the passes of the saw in the first direction. Accordingly, during the passes of the saw in the orthogonal direction, no material is left at the intersections of the saw streets 607 and 608 to form small chips.

The frame structures of the lead frame array 614 also include surrounding bars 635 around edges of the array of lead frames 610. Although FIG. 6 only shows four lead frames 612 in the array 610, it will be appreciated that the number of lead frames in the array may be substantially greater than four. Also there may be more than one array 610 formed in the lead frame sheet. Although the surrounding bars 635 are shown in FIG. 6 as being similar to the intermediate bars 631 and 632 common to adjacent lead frames they may in fact be stronger, for example wider, than the intermediate bars 631 and 632. In any event, singulating the devices 40 could involve multiple passes of the saw blade to detach the surrounding bars 635 around the edges of the array(s).

In this embodiment of the present invention, the lead frames 612 are supported during the singulation operation. Singulation includes sawing beside each of the surrounding bars 635 without sawing the surrounding bars 635 longitudinally so as to saw off material from each surrounding bar 635, and removing the sawn-off material from the surrounding bars 635 before sawing through the leads on each side of the intermediate common bars 631 or 632. In this way, the saw blades do not have to pass through the surrounding bars 635 when sawing off the intermediate common bars 631 and 632 and the number of passes of the saw blade through the surrounding bars 635 is reduced.

Cavities may be formed in the ends of the leads 620 to form recesses 34, extending partly into the thickness of the lead frame 612, for example by semi-etching. The cavities could be elongate cavities extending across the common bars 632, like the cavities 30 shown in FIG. 3. However, in accordance with the present invention, the cavities are specifically limited to dimples 636 straddling the saw streets 607 and 708 and do not traverse the common bars 632. The inventors have determined that limiting the scope of the dimples 636 provides significant advantages over the conventional lead frame. Limiting the size and shape of the dimples 636 avoids weakening the lead frame structure, enhances the ease and quality of wire bonds, and significantly reduces mold resin bleed, which can be a cause of weak or compromised electrical connection between the semiconductor die and the leads 620. During the singulation process, the saw blades cut through the leads 620 at the cavities 636, leaving the ends of the cavities 636 to form the recesses 34 extending partially into the exposed ends of the leads 620 and into the contact surface portions 628.

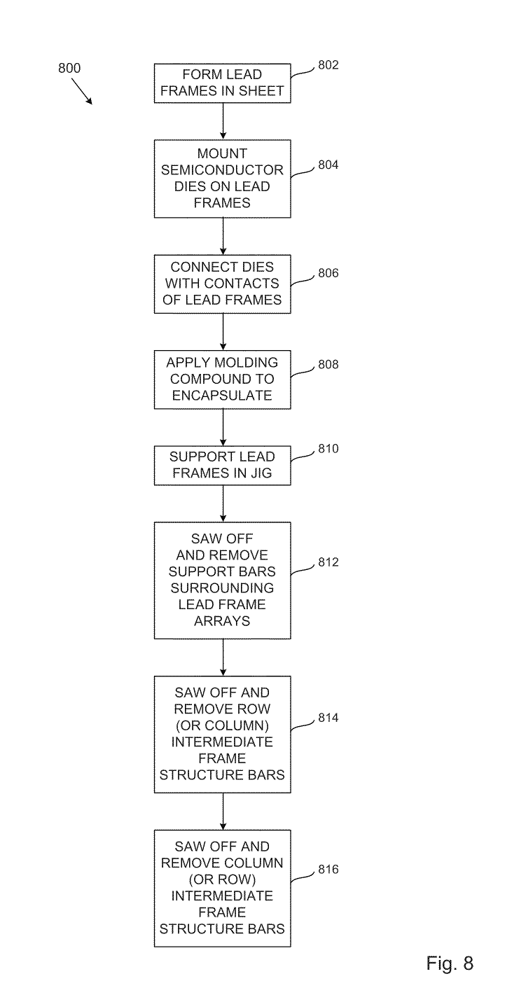

FIG. 8 is a flow chart of an example of a method 800 of making semiconductor devices. The method 800 starts at step 802 with forming lead frame arrays such as 610 of lead frames 612. In accordance with the present invention, the lead frames should include the dimples 636 on the leads 620. Semiconductor dies such as the die 2 are mounted on and attached to the lead frames at step 804. The dies also are electrically connected to electrical contact elements such as 620 of the lead frames at step 806. Molding compound such as 42 is applied to encapsulate the lead frames at step 808. The devices such as 40 are then singulated.

The singulation starts at step 810 by supporting the lead frames such as 612 in a jig. Singulation includes at step 812 sawing beside each of the support bars such as 635 of the frame structures 614 surrounding the array(s) 610 without sawing the surrounding bars 635 longitudinally so as to saw off material from each surrounding bar 635, and removing the sawn-off material from the surrounding bars 635 before sawing through the leads 620 on each side of the intermediate common bars 631 or 632. It should be noted that sawing beside the support bars instead of down the middle of the support bars extends the life of the saw blade and thus saves manufacturing time and cost.

At step 814, intermediate frame structure (row or column) common bars such as 631 (or 632) are removed by sawing through the leads 620 in saw streets 607 (or 608) on each side of each row (or column) common bar 631 (or 632) without sawing the common bar 631 or 632 longitudinally before proceeding at step 916 to sawing off the orthogonal intermediate common bars 632 (or 631) in the orthogonal direction saw streets 608 (or 607).

The example of a method of assembling semiconductor devices described above with reference to FIGS. 6 to 8 provides a substantial improvement in saw blade life and reduction in saw blade damage during singulation. The process provides a substantial reduction in the incidence and size of smearing and burrs during the singulation process. This leads to a reduction in incidence of defects including short-circuit between adjacent contact elements and inadequate co-planarity, with consequent improved product yield and reduced manufacturing cost. The process also facilitates the provision of recesses 34 in the bottom electrical contact portions 28 and the exposed outer ends of the leads 20 of the semi-completed conductor package 740. During solder mounting of the completed device 740 on a support (e.g., PCB), solder can reflow up into the recesses 34 and provide a visual check of soldering process quality.

In the foregoing specification, the invention has been described with reference to specific examples of embodiments of the invention. It will, however, be evident that various modifications and changes may be made therein without departing from the broader spirit and scope of the invention as set forth in the appended claims. For example, the connections may be any type of connection suitable to transfer signals from or to the respective nodes, units or devices, for example via intermediate devices. Accordingly, unless implied or stated otherwise the connections may for example be direct connections or indirect connections.

Where the context admits, it will be understood that the semiconductor material described herein can be any semiconductor material or combinations of materials, such as gallium arsenide, silicon germanium, silicon-on-insulator (SOI), silicon, mono-crystalline silicon, the like, and combinations of the above.

Where the context admits, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, any reference signs placed between parentheses shall not be construed as limiting the claim. Where the context admits, terms such as “first” and “second” are used to distinguish arbitrarily between the elements such terms describe and these terms are not necessarily intended to indicate temporal or other prioritization of such elements.

1. A method of assembling semiconductor devices for surface mounting, comprising the steps of:
forming at least one two-dimensional array of lead frames in a sheet of electrically conductive material, each of said lead frames comprising at least one pair of sets of leads disposed at opposite sides of the corresponding lead frame and respective supporting frame structures, said leads presenting respective electrical contact surface portions, and said supporting frame structures comprising intersecting orthogonal intermediate common bars between adjacent ones of said lead frames, sets of said leads of the respective adjacent lead frames connecting with and extending transversely to said common bars;
mounting a semiconductor die in each of said lead frames;
connecting each of said semiconductor dies electrically with said leads of the corresponding lead frame;
encapsulating said semiconductor dies with a molding compound, wherein said encapsulated dies present active faces and opposite faces of the semiconductor devices with said contact surface portions of said leads exposed at said active faces of the semiconductor devices; and
singulating said semiconductor devices, including sawing in a first direction through said leads on each side of said intermediate common bars without sawing said intermediate common bars longitudinally so as to saw off material of the corresponding intermediate common bars, and removing the material sawn off from said common bars in said first direction before sawing off material from said intermediate common bars in an orthogonal direction.

2. The method of assembling semiconductor devices of claim 1, wherein forming said array of lead frames includes forming recesses in said leads, said recesses extending partially into said contact surface portions.

3. The method of assembling semiconductor devices of claim 2, wherein forming said array of lead frames includes forming cavities in said leads, and singulating said semiconductor devices includes sawing through said cavities in said leads, leaving said recesses extending partially into said exposed ends of said leads and into said contact surface portions.

4. The method of assembling semiconductor devices of claim 1, wherein singulating said semiconductor devices includes sawing through said leads using a pair of saw blades that saw simultaneously through said leads on respective sides of said common bar without sawing said common bar longitudinally.

5. The method of assembling semiconductor devices of claim 1, wherein singulating said semiconductor devices includes supporting said lead frames in a jig and washing away said sawn-off material from each common bar away as it is sawn off.

6. The method of assembling semiconductor devices of claim 1, wherein singulating said semiconductor devices includes sawing through said molding compound as well as said leads to form edges of said semiconductor devices with exposed ends of said leads.

7. The method of assembling semiconductor devices of claim 1, wherein said supporting frame structures include surrounding bars around edges of said array connecting with and extending transversely to sets of said leads, and singulating said semiconductor devices includes sawing through said leads beside each of said surrounding bars without sawing said surrounding bars longitudinally so as to saw off material from each surrounding bar, and removing the sawn-off material from said surrounding bars before sawing through said leads on each side of said intermediate common bars.

8. The method of assembling semiconductor devices of claim 1, wherein singulating said semiconductor devices includes sawing in said first direction through said leads on successive sides of the corresponding intermediate common bars using a single saw blade and removing the material of said intermediate common bars sawn off in said first direction before sawing off material from said intermediate common bars in an orthogonal direction.

9. A method of assembling semiconductor devices for surface mounting, comprising:
mounting semiconductor dies to corresponding lead frames, wherein the lead frames are formed in an array of lead frames in a sheet of electrically conductive material, each of said lead frames comprising at least one pair of sets of leads disposed at opposite sides of the corresponding lead frame and respective supporting frame structures, said leads of each set presenting respective electrical contact surface portions, and said supporting frame structures comprising intermediate common bars between adjacent ones of said lead frames and surrounding bars around edges of said array;
connecting each of said semiconductor dies electrically with said leads of the corresponding lead frame;
applying a molding compound to encapsulate said semiconductor dies and to present active faces and opposite faces of the semiconductor devices with said contact surface portions of said leads exposed at said active faces of the semiconductor devices; and
singulating said semiconductor devices, including supporting said lead frames, sawing beside each of said surrounding bars without sawing said surrounding bars longitudinally, and removing the sawn-off material from said surrounding bars before sawing through said leads on each side of said intermediate common bars.

10. The method of assembling semiconductor devices of claim 9, wherein the leads of each of said lead frames of said lead frame array include recesses extending partially into said contact surface portions and said singulating includes sawing through said leads at said recesses.

11. The method of assembling semiconductor devices of claim 9, wherein singulating said semiconductor devices includes supporting said lead frames in a jig and washing away said sawn-off material from each common bar away as it is sawn off.

12. The method of assembling semiconductor devices of claim 9, wherein singulating said semiconductor devices includes sawing through said molding compound as well as said leads to form edges of said semiconductor devices with exposed ends of said leads.

13. A method of assembling semiconductor devices for surface mounting, comprising:
mounting semiconductor dies to corresponding lead frames, wherein the lead frames are formed in an array of lead frames in a sheet of electrically conductive material, each of said lead frames comprising at least one pair of sets of leads disposed at opposite sides of the corresponding lead frame and respective supporting frame structures, said leads of each set presenting respective electrical contact surface portions, and said supporting frame structures comprising intermediate common bars between adjacent ones of said lead frames and surrounding bars around edges of said array, and wherein said electrical contact surface portions of said leads include a cavity therein, and wherein said cavities do not extend into said intermediate common bars;
connecting each of said semiconductor dies electrically with said leads of the corresponding lead frame;
applying a molding compound to encapsulate said semiconductor dies and to present active faces and opposite faces of the semiconductor devices with said contact surface portions of said leads exposed at said active faces of the semiconductor devices; and
singulating said semiconductor devices, including supporting said lead frames, sawing beside each of said surrounding bars without sawing said surrounding bars longitudinally, and removing the sawn-off material from said surrounding bars, and sawing through said leads at said recesses on each side of said intermediate common bars, thereby separating the semiconductor devices.
